(19) United States
(12) Patent Application Publication
(10) Pub. No.: US 2025/0294779 A1
(43) Pub. Date: Sep. 18, 2025

(54) MAGNETIC MEMORY DEVICE

(71) Applicant: Kioxia Corporation, Tokyo (JP)

(72) Inventors: Naoki AKIYAMA, Yokkaichi Mie (JP); Kenichi YOSHINO, Seongnam-si Gyeonggi-do (KR); Hyungjun CHO, Seongnam-si Gyeonggi-do (KR); Hyung-Woo AHN, Seongnam-si Gyeonggi-do (KR); Takuya SHIMANO, Seoul (KR)

(73) Assignee: Kioxia Corporation, Tokyo (JP)

(21) Appl. No.: 19/074,945

(22) Filed: Mar. 10, 2025

(30) Foreign Application Priority Data
Mar. 18, 2024 (JP) 2024-042154

(51) Int. Cl. H10B 61/00; H10N 50/01; H10N 50/10; H10N 50/85

(52) U.S. Cl. CPC H10B 61/10; H10N 50/01; H10N 50/10; H10N 50/85

(57) ABSTRACT

According to one embodiment, a magnetic memory device includes a lower structure, first and second stacked structures provided on the lower structure, first and second boron-containing layers containing boron (B) and provided on side surfaces of the first and second stacked structures, respectively. Each of the first and second stacked structures includes, a basic portion including a first magnetic layer having a variable magnetization direction, a second magnetic layer having a fixed magnetization direction, and a non-magnetic layer provided between the first and second magnetic layers, lower and upper portions provided on lower and upper layer sides of the basic portion, respectively, and having electrical conductivity.

### CROSS-REFERENCE TO RELATED APPLICATIONS

This application is based upon and claims the benefit of priority from Japanese Patent Application No. 2024-042154, filed Mar. 18, 2024, the entire contents of which are incorporated herein by reference.

### FIELD

Embodiments described herein relate generally to a magnetic memory device.

### BACKGROUND

A magnetic memory device has been proposed in which a plurality of magnetoresistance effect elements are integrated on a semiconductor substrate.

### BRIEF DESCRIPTION OF THE DRAWINGS

FIG. 1 is a cross-sectional view schematically showing a configuration of a magnetic memory device according to an embodiment.

FIG. 2 is a cross-sectional view perpendicular to a Z direction, schematically showing a stacked structure and a boron-containing layer in the magnetic memory device according to the embodiment.

FIG. 3 is a cross-sectional view perpendicular to the Z direction, schematically showing an electrode, an insulating portion of a lower insulating layer (an insulating portion provided in an area underneath the stacked structure), a metal-containing layer and an extending portion of the boron-containing layer in the magnetic memory device according to the embodiment.

FIG. 4 is a cross-sectional view schematically showing a part of a method of manufacturing the magnetic memory device according to the embodiment.

FIG. 5 is a cross-sectional view schematically showing a part of a method of manufacturing the magnetic memory device according to the embodiment.

FIG. 6 is a cross-sectional view schematically showing a part of a method of manufacturing the magnetic memory device according to the embodiment.

FIG. 7 is a cross-sectional view schematically showing a part of a method of manufacturing the magnetic memory device according to the embodiment.

FIG. 8 is a perspective view schematically showing a configuration of an example in which the magnetic memory device according to the embodiment is applied.

### DETAILED DESCRIPTION

In general, according to one embodiment, a magnetic memory device includes: a lower structure; a first stacked structure provided on the lower structure; a second stacked structure provided on the lower structure and adjacent to the first stacked structure; a first boron-containing layer containing boron (B) and provided on a side surface of the first stacked structure; a second boron-containing layer containing boron (B) and provided on a side surface of the second stacked structure, wherein each of the first and second stacked structures includes: a basic portion including a first magnetic layer having a variable magnetization direction, a second magnetic layer having a fixed magnetization direction, and a non-magnetic layer provided between the first magnetic layer and the second magnetic layer; a lower portion provided on a lower layer side of the basic portion and having electrical conductivity; and an upper portion provided on an upper layer side of the basic portion and having electrical conductivity.

Embodiments will be described hereinafter with reference to the accompanying drawings.

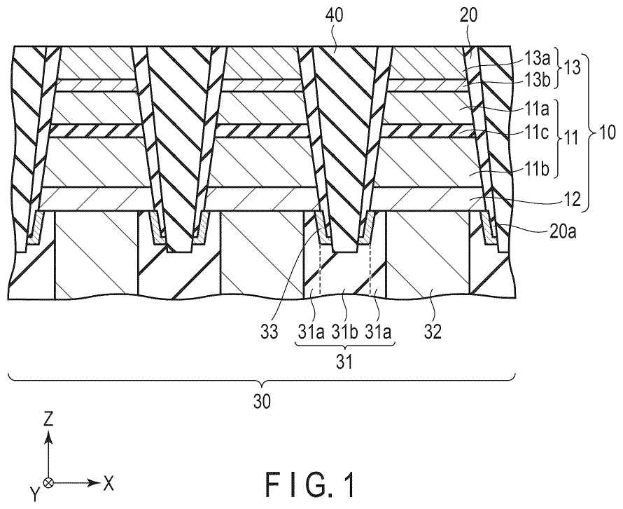

FIG. 1 is a cross-sectional view schematically showing a configuration of a magnetic memory device in an embodiment.

The magnetic memory device of the embodiment is provided on a semiconductor substrate (not shown) and includes a plurality of stacked structures 10, a plurality of boron-containing layers 20, a lower structure 30, and an upper insulating layer 40.

The plurality of stacked structures 10 are provided on the lower structure 30 and are arranged in an array along an X direction and a Y direction. Each of the stacked structures 10 has a configuration in which a plurality of layers are stacked along the Z direction. Note here that the X direction, Y direction, and Z direction are directions intersecting each other. More specifically, the X, Y and Z directions are orthogonal to each other.

Each of the stacked structures 10 functions as a magnetic tunnel junction (MTJ) element, which is a magnetoresistance effect element. Each of the stacked structures 10 includes a basic portion 11, a lower portion 12, and an upper portion 13.

The basic portion 11 includes a storage layer (first magnetic layer) 11a, a reference layer (second magnetic layer) 11b, and a tunnel barrier layer (nonmagnetic layer) 11c, and functions as a basic portion of the magnetoresistance effect element.

The storage layer 11a is a ferromagnetic layer having a variable magnetization direction. The variable magnetization direction means that the magnetization direction varies in response to a predetermined writing current. The storage layer 11a contains at least one element selected from iron (Fe) and cobalt (Co). More specifically, the storage layer 11a is formed from an FeCoB layer containing iron (Fe), cobalt (Co) and boron (B).

The reference layer 11b is a ferromagnetic layer having a fixed magnetization direction, and includes a first layer portion and a second layer portion stacked one on another along the Z direction. The fixed magnetization direction means that the magnetization direction does not vary in response to a predetermined writing current.

The first layer portion is provided on a side close to the tunnel barrier layer 11c and contains at least one element selected from iron (Fe) and cobalt (Co). More specifically, the first layer portion is formed from an FeCoB layer containing iron (Fe), cobalt (Co) and boron (B).

The second layer portion is provided on a side distant from the tunnel barrier layer 11c and contains at least platinum (Pt). More specifically, the second layer portion has a superlattice structure in which a plurality of platinum (Pt) layers and a plurality of cobalt (Co) layers are stacked alternately.

The tunnel barrier layer 11c is an insulating layer provided between the storage layer 11a and the reference layer 11b. More specifically, the tunnel barrier layer 11c is formed from an MgO layer containing magnesium (Mg) and oxygen (O).

When the magnetization direction of the storage layer 11a is parallel to the magnetization direction of the reference layer 11b, the magnetoresistance effect element exhibits a low-resistance state having a relatively low resistance. When the magnetization direction of the storage layer 11a is antiparallel to the magnetization direction of the reference layer 11b, the magnetoresistance effect element exhibits a high-resistance state having a relatively high resistance. Therefore, the magnetoresistance effect element can store binary data according to its resistance state. The resistance state of the magnetoresistance effect element can be set according to the direction of the current flowing through the magnetoresistance effect element.

Note that the basic portion 11 of the magnetoresistance effect element shown in FIG. 1 has a top-free structure in which the storage layer 11a is located on an upper layer side of the reference layer 11b, but the basic portion 11 may as well have a bottom-free structure in which the storage layer 11a is located on a lower layer side of the reference layer 11b.

The lower portion 12 of the stacked structure 10 is provided on an lower layer side of the basic portion 11 and has electrical conductivity. The lower portion 12 is formed of a conductive material containing at least one element selected from hafnium (Hf), tungsten (W), titanium (Ti), and aluminum (Al). For example, the lower portion 12 may be formed from one of an Hf layer, W layer, Ti layer, and Al layer, or it may be formed from a stacked body of two or more layers of the Hf layer, W layer, Ti layer, and Al layer. Further, the lower portion 12 may as well include a layer containing two or more elements of Hf, W, Ti, and Al within the same layer. In this embodiment, the lower portion 12 contains hafnium at least in its lower most region.

The upper portion 13 of the stacked structure 10 is provided on an upper layer side of the basic portion 11 and has electrical conductivity. The upper portion 13 contains at least one element selected from hafnium (Hf), tungsten (W), titanium (Ti), aluminum (Al), and ruthenium (Ru). The upper portion 13 includes a hard mask portion 13a and an intermediate portion 13b.

The hard mask portion 13a is the uppermost layer portion of the stacked structure 10 and functions as a hard mask when forming the pattern of the stacked structure 10. The hard mask portion 13a is formed of a conductive material containing at least one element selected from hafnium (Hf), tungsten (W), titanium (Ti), and aluminum (Al). For example, the hard mask portion 13a may be formed from one of the Hf layer, W layer, Ti layer, and Al layer, or a stacked body of two or more of the Hf layer, W layer, Ti layer, and Al layer stacked one on another. Further, the hard mask portion 13a may as well include a layer containing two or more elements of Hf, W, Ti, and Al in the same layer.

The intermediate portion 13b is provided between the basic portion 11 and the hard mask portion 13a, and is formed of a conductive material. For example, the intermediate portion 13b is formed from a ruthenium (Ru) layer.

Each of the plurality of boron-containing layers 20 is provided on a side surface (side wall) of a respective one of the plurality of stacked structures 10. More specifically, each of the boron-containing layers 20 is provided to surround the side surface of the respective one of the stacked structures 10. The boron-containing layers 20 are each formed of an insulating material containing boron (B). More specifically, the boron-containing layers 20 are each formed of boron nitride (BN) containing boron (B) and nitrogen (N).

Each boron-containing layer 20 may be provided on the entire side surface of the stacked structure 10, or it may be provided on only a part of the side surface of the stacked structure 10. But, note here that the boron-containing layer 20 should preferably be provided in such a fashion that surrounds the entire side surface of at least the basic portion 11 of the stacked structure 10. In this embodiment, the boron-containing layer 20 is continuously provided on the entire side surface of the stacked structure 10 which includes the base portion 11, the lower portion 12 and the upper portion 13. Further, the boron-containing layer 20 may as well include an extending portion 20a that extends to an upper portion of the lower structure 30.

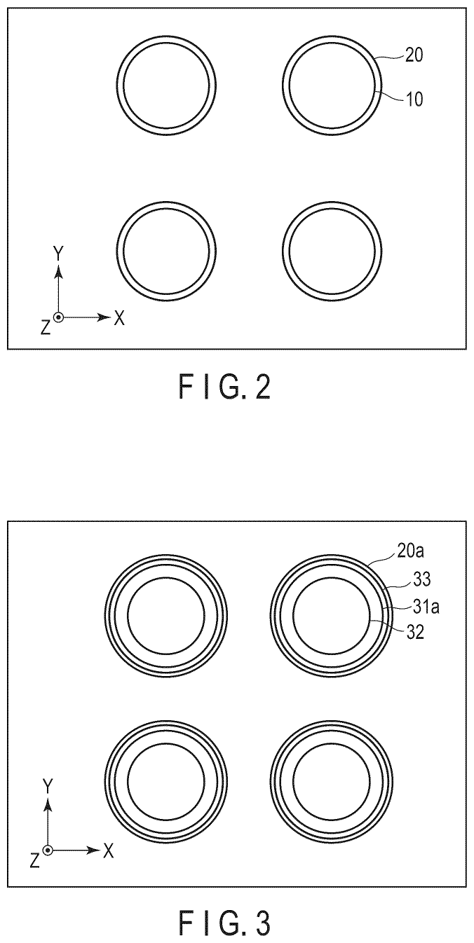

FIG. 2 is a cross-sectional view perpendicular to the Z direction, schematically showing the stacked structure 10 and the boron-containing layer 20. As can be seen in FIG. 2, the pattern of the boron-containing layer 20 is provided in a manner that surrounds the circular pattern of the stacked structure 10.

The lower structure 30 includes a lower insulating layer 31, a plurality of electrodes 32, and a plurality of metal-containing layers 33.

The lower insulating layer 31 functions as an interlayer insulating layer and includes a plurality of insulating portions 31a, each of which is provided in an area below the respective one of the stacked structures 10, and an insulating portion 31b provided in an area on an outer side of the plurality of insulating portions 31a. More specifically, the pattern of the insulating portions 31b is provided to surround the pattern of the respective one of the insulating portions 31a. The insulating portion 31b includes an upper surface that is located at a level lower than that of upper surfaces of the respective insulating portions 31a. In other words, the insulating portion 31b is recessed with respect to the respective insulating portions 31a. The lower insulating layer 31 is formed of an insulating material such as silicon oxide or silicon nitride.

Each of the plurality of electrodes 32 is connected to a lower surface of the respective one of the plurality of stacked structures 10. In other words, each of the electrodes 32 is connected to the lower surface of the lower portion 12 of the respective one of the stacked structures 10. The side surface of each of the electrodes 32 is surrounded by the insulating portion 31a of the respective lower insulating layer 31.

Each of the plurality of metal-containing layers 33 is provided on a side surface of the respective one of the insulating portions 31a. More specifically, each of the metal-containing layers 33 is provided so as to surround the side surface of the upper portion of the respective one of the insulating portions 31a.

Each of the metal-containing layers 33 contains metal elements contained in each of the respective stacked structure 10. More specifically, the metal-containing layers 33 contain at least one element selected from hafnium (Hf), tungsten (W), titanium (Ti), aluminum (Al), iron (Fe), cobalt (Co), platinum (Pt), and ruthenium (Ru). In particular, the metal-containing layers 33 contain Hf at a relatively high ratio.

As already mentioned, the boron-containing layer 20 may include an extending portion 20a that extends to an upper portion of the lower structure 30, in which case the extending portion 20a is provided on the side surface of the metal-containing layer 33.

In addition, there is no layer containing boron (B) provided on the upper surface of the insulating portion 31b of the lower insulating layer 31, except for the part near the outer edge of the insulating portion 31b (except for the part near the boundary between the insulating portion 31a and the insulating portion 31b). In other words, the portion near the outer edge of the insulating portion 31b on the upper surface of the insulating portion 31b includes a part containing boron (B).

FIG. 3 is a diagram schematically showing a cross-section perpendicular to the Z-direction of the electrode 32, the insulating portion 31a of the lower insulating layer 31, the metal-containing layer 33, and the extending portion 20a of the boron-containing layer 20. As can be seen in FIG. 3, the pattern of the insulating portion 31a of the lower insulating layer 31 is provided to surround the circular pattern of the electrode 32, the pattern of the metal-containing layer 33 is provided to surround the pattern of the insulating portion 31a, and the pattern of the extending portion 20a of the boron-containing layer 20 is provided to surround the pattern of the metal-containing layer 33.

The upper insulating layer 40 surrounds the side surface of each of a plurality of structures each including the stacked structure 10 and the boron-containing layer 20. Further, the upper insulating layer 40 extends to the upper surface of the insulating portion 31b of the lower insulating layer 31. The upper insulating layer 40 functions as an interlayer insulating layer and is formed of a material that is different from the material of the boron-containing layers 20. For example, the upper insulating layer 40 is formed from an insulating material such as silicon oxide or silicon nitride.

As described above, in this embodiment, the boron-containing layers 20 are each provided on the side surface of the respective one of the stacked structures 10. With this structure, it is possible to electrically isolate adjacent stacked structures 10 reliably from each other, as will be described below. In other words, it is possible to reliably isolate adjacent magnetoresistance effect elements electrically from each other.

Normally, when forming the pattern of the stacked structures 10, a hard mask is used as an etching mask, and the stacked film for the stacked structures 10 is etched by ion beam etching (IBE) or the like. In this case, a metal-containing layer (residue layer) containing the metal elements contained in the stacked film is formed in an area between adjacent stacked structures 10, and therefore there is a risk that the electrical isolation between adjacent stacked structures 10 may be impaired. Further, there is also a risk that a metal-containing layer (residue layer) may be formed on the side surface of a stacked structure 10. In this case, the electrical isolation between the storage layer 11a and the reference layer 11b may be impaired. In particular, when Hf is contained in the lower portion 12 of the stacked structure 10, a metal containing layer (residue layer) containing Hf will be formed, thereby making it difficult to accurately remove the metal-containing layer (residue layer) containing Hf.

In this embodiment, with the boron-containing layer 20 thus provided on the side surface of the stacked structure 10, it is possible to prevent drawbacks such as described above, a detail of which will now be described.

When hafnium (Hf) generated in the etching carried out to form the pattern of the stacked structure 10 combines with oxygen in the interlayer insulating layer or the air, hafnium oxide is formed. Note that it is not easy to remove the metal-containing layer (residue layer) containing hafnium oxide by etching.

In this embodiment, the boron-containing layer 20 is formed after the stacked structure 10 is formed. Boron (B) is more easily oxidized than hafnium (Hf). In other words, the bond between boron and oxygen is more stable than the bond between hafnium and oxygen. With these properties, when the etching is carried out after the boron-containing layer 20 is formed, the oxygen in the hafnium oxide in the metal-containing layer (residual layer) combines with boron (B), and the hafnium oxide is reduced to hafnium (Hf). Hafnium (Hf) is easier to etch than hafnium oxide, and therefore the metal-containing layer (residue layer) can be easily removed.

Therefore, in this embodiment, it is possible to electrically isolate adjacent magnetoresistance effect elements (adjacent stacked structures 10) reliably from each other.

Next, a method of manufacturing the magnetic memory device in this embodiment will be explained with reference to FIGS. 4 to 7 and FIG. 1.

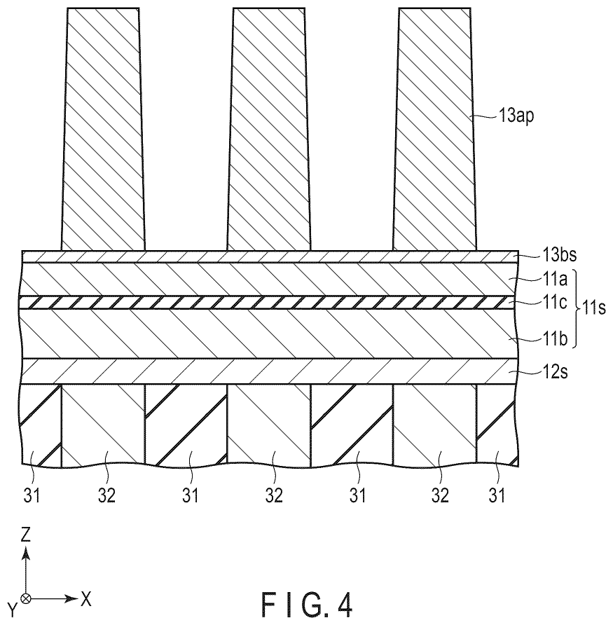

First, as shown in FIG. 4, a stacked film for the stacked structures 10 is formed on a structure that includes lower insulating layers 31 and electrodes 32. More specifically, a lower portion layer 12s, a basic portion layer 11s (a storage layer 11a, a reference layer 11b, and a tunnel barrier layer 11c), an intermediate portion layer 13bs, and a hard mask layer are formed. Then, the hard mask layer is patterned to form a hard mask pattern 13ap.

Next, as shown in FIG. 5, the intermediate portion layer 13bs, the basic portion layer 11s, and the lower portion layer 12s are etched by IBE, using the hard mask pattern 13ap as a mask. At this time, the hard mask pattern 13ap is etched as well, and the height (thickness) of the hard mask pattern 13ap is reduced. In this manner, the pattern of the stacked structures 10 each including the basic portion 11 (storage layer 11a, reference layer 11b, and tunnel barrier layer 11c), the lower portion 12, and the upper portion 13 (hard mask portion 13a and intermediate portion 13b), is formed. In this etching process, over-etching is performed to ensure that adjacent stacked structures 10 are physically separated from each other. Thus, a part of the lower insulating layer 31 is etched, thus forming a recess portion 31r. Further, on the bottom surface and side surface of the recess portion 31r, a metal-containing layer (residue layer) 33 containing the metal elements contained in the stacked structure 10 is formed. Note that the metal-containing layer (residue layer) 33 contains hafnium oxide and the like.

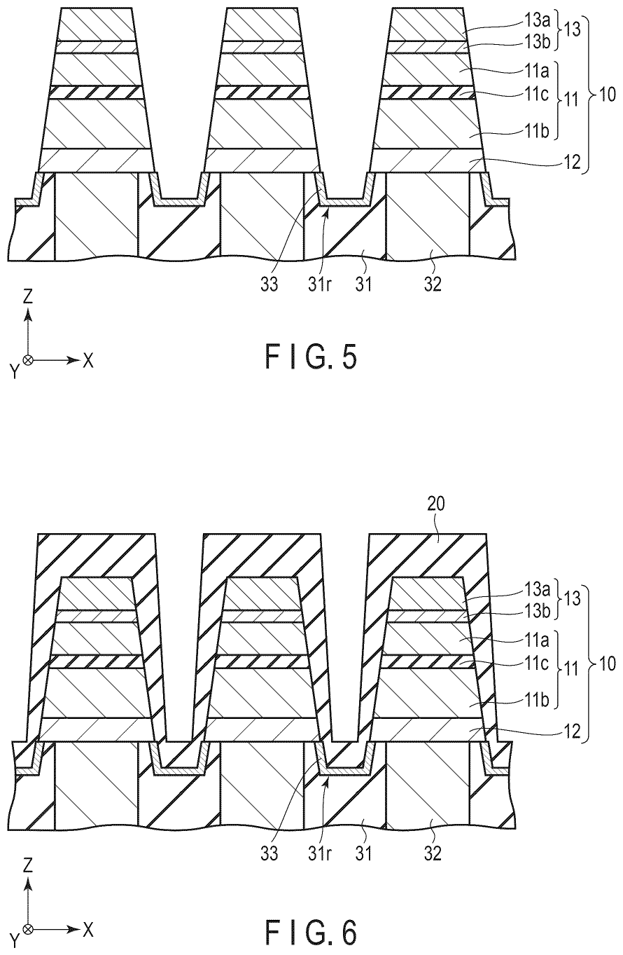

Next, as shown in FIG. 6, a boron-containing layer 20 is formed so as to cover the structure obtained in the processing step shown in FIG. 5. More specifically, a boron nitride (BN) layer is formed as the boron-containing layer 20.

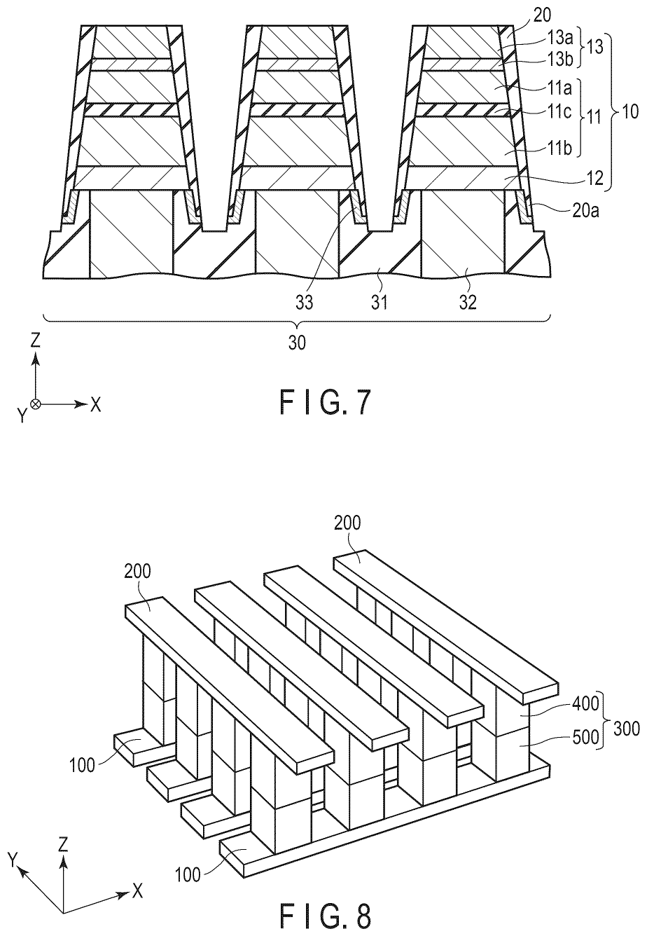

Next, as shown in FIG. 7, the boron-containing layer 20 is subjected to anisotropic etching by reactive ion etching (RIE). For the etching gas, a gas containing chlorine (Cl) (for example, Cl₂ gas) is used. With the anisotropic etching, the portion of the boron-containing layer 20 formed on the upper surface of the stacked structure 10 and the bottom surface of the recess portion 31r of the lower insulating layer 31 is removed, and only the portion of the boron-containing layer 20 formed on the side surface of the stacked structure 10 and the side surface of the metal-containing layer 33 remains. Further, with this anisotropic etching, the metal-containing layer 33 formed on the bottom surface of the recess portion 31r can be removed as well.

As described above, the metal-containing layer (residue layer) 33 contains hafnium oxide and the like. Boron (B) is more easily oxidized than hafnium (Hf), and the bond between boron and oxygen is more stable than the bond between hafnium and oxygen. With the properties by forming a boron-containing layer 20 before performing the anisotropic etching described above, the oxygen in the hafnium oxide bonds with the boron, and hafnium is produced. As a result, it becomes possible to easily remove the metal-containing layer (residue layer) 33 containing hafnium.

Note here that for the etching gas, a type that contains chlorine (Cl) and boron (B) (for example, a mixture gas of Cl₂ gas and BCl₃ gas) may be used. Thus, by adding a gas containing boron (B), it is possible to further promote the removal of the metal-containing layer (residue layer) 33 containing hafnium.

After that, the upper insulating layer 40 is formed on the structure obtained in the processing step shown in FIG. 7, and then the upper insulating layer 40 is planarized, thus obtaining the structure shown in FIG. 1.

As described above, according to the manufacturing method explained above, by forming the boron-containing layer 20, it is possible to easily remove the metal-containing layer (residual layer) 33. Therefore, with the manufacturing method described above, adjacent magnetoresistance effect elements (adjacent stacked structures 10) can be electrically isolated reliably.

Next, an example of application of the magnetic memory device of this embodiment will be explained. FIG. 8 is a perspective view schematically showing a configuration of an example in which the magnetic memory device of this embodiment is applied.

The memory device shown in FIG. 8 comprises a plurality of wiring lines 100, a plurality of wiring lines 200, and a plurality of memory cells 300 each provided between a respective one of the wiring lines 100 and a respective one of the wiring lines 200.

The wiring lines 100 each extend along the X direction, and the wiring lines 200 each extend along the Y direction. The wiring lines 100 correspond to word lines and the wiring lines 200 correspond to bit lines, or vice versa.

Each of the plurality of memory cells 300 contains a magnetoresistance effect element 400 and a selector (switching element) 500, and has a configuration in which the magnetoresistance effect element 400 and the selector 500 are stacked one on another along the Z direction. In other words, each memory cell 300 has a configuration in which the magnetoresistance effect element 400 and the selector 500 are connected to each other in series.

The basic structure of each magnetoresistance effect element 400 corresponds to the structure described in the above-provided embodiment (a structure including a stacked structure 10 and a boron-containing layer 20 and the like). The selector 500 is a two-terminal switching element that has the characteristic of changing from an off state to an on state when the voltage applied between the two terminals reaches a threshold voltage.

When a voltage is applied between a wiring line 100 and a wiring line 200, and the voltage applied to the selector 500 reaches or exceeds the threshold voltage, the selector 500 switches from the off state to the on state. As a result, a current flows through the magnetoresistance effect element 400 connected in series with the selector 500, and thus it is possible to carry out write or read with respect to the magnetoresistance effect element 400.

By applying the magnetic memory device of this embodiment to a memory device such as the one shown in FIG. 8, a memory device having excellent characteristics and reliability can be obtained.

Further, the memory device shown in FIG. 8 has a structure in which the magnetoresistance effect element 400 is located on an upper layer side of the selector 500, but it is also possible to have a structure in which the magnetoresistance effect element 400 is located on a lower layer side of the selector 500.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A magnetic memory device comprising:
a lower structure;
a first stacked structure provided on the lower structure;
a second stacked structure provided on the lower structure and adjacent to the first stacked structure;
a first boron-containing layer containing boron (B) and provided on a side surface of the first stacked structure;
a second boron-containing layer containing boron (B) and provided on a side surface of the second stacked structure,
wherein
each of the first and second stacked structures includes:
a basic portion including a first magnetic layer having a variable magnetization direction, a second magnetic layer having a fixed magnetization direction, and a non-magnetic layer provided between the first magnetic layer and the second magnetic layer;
a lower portion provided on a lower layer side of the basic portion and having electrical conductivity; and
an upper portion provided on an upper layer side of the basic portion and having electrical conductivity.

2. The device of claim 1, wherein
each of the first and second boron-containing layers further contains nitrogen (N).

3. The device of claim 1, wherein
the first magnetic layer contains at least one element selected from iron (Fe) and cobalt (Co).

4. The device of claim 1, wherein
the second magnetic layer contains at least one element selected from iron (Fe) and cobalt (Co).

5. The device of claim 4, wherein
the second magnetic layer further contains platinum (Pt).

6. The device of claim 1, wherein
the non-magnetic layer contains magnesium (Mg) and oxygen (O).

7. The device of claim 1, wherein
the lower portion contains at least one element selected from hafnium (Hf), tungsten (W), titanium (Ti), and aluminum (Al).

8. The device of claim 1, wherein
the upper portion contains at least one element selected from hafnium (Hf), tungsten (W), titanium (Ti), aluminum (Al) and ruthenium (Ru).

9. The device of claim 1, wherein
the lower structure includes a lower insulating layer, and
the lower insulating layer includes:
a first insulating portion provided in an area below the first stacked structure,
a second insulating portion provided in an area below the second stacked structure; and
a third insulating portion provided in an area on an outer side of the first insulating portion and the second insulating portion, and including an upper surface lower than an upper surface of the first insulating portion and an upper surface of the second insulating portion.

10. The device of claim 9, wherein
the lower structure further includes:
a first electrode connected to a lower surface of the first stacked structure and including a side surface surrounded by the first insulating portion; and
a second electrode connected to a lower surface of the second stacked structure and including a side surface surrounded by the second insulating portion.

11. The device of claim 9, wherein
the lower structure further includes:
a first metal-containing layer provided on a side surface of the first insulating portion and containing at least one metal element contained in the first stacked structure; and
a second metal-containing layer provided on a side surface of the second insulating portion and containing at least one metal element contained in the second stacked structure.

12. The device of claim 11, wherein
the first boron-containing layer includes a first extending portion provided on a side surface of the first metal-containing layer, and
the second boron-containing layer includes a second extending portion provided on a side surface of the second metal-containing layer.

13. The device of claim 11, wherein
each of the first and second metal-containing layers contains at least one element selected from hafnium (Hf), tungsten (W), titanium (Ti), aluminum (Al), iron (Fe), cobalt (Co), platinum (Pt), and ruthenium (Ru).

14. The device of claim 13, wherein
no layer containing boron (B) is provided on an upper surface of the third insulating portion except for a part near an outer edge of the third insulating portion.

15. The device of claim 1, further comprising:
an upper insulating layer that surrounds a side surface of a structure including the first stacked structure and the first boron-containing layer, and surrounds a side surface of a structure including the second stacked structure and the second boron-containing layer.

16. A method of manufacturing a magnetic memory device, the method comprising:
forming, on a structure including a lower insulating layer, a stacked film including a basic portion layer including a first magnetic layer having a variable magnetization direction, a second magnetic layer having a fixed magnetization direction, and a nonmagnetic layer provided between the first magnetic layer and the second magnetic layer, a lower portion layer provided on a lower layer side of the basic portion layer and having electrical conductivity, and an upper portion layer provided on an upper layer side of the basic portion layer and having electrical conductivity;
forming a hard mask pattern by patterning a hard mask layer included in the upper portion layer;
carrying out etching using the hard mask pattern as a mask to form a stacked structure including patterns of the basic portion layer, the lower portion layer, and the upper portion layer, and to form a recess portion in the lower insulating layer;
forming a boron-containing layer containing boron (B) so as to cover a structure obtained by the etching using the hard mask pattern as the mask; and
etching the boron-containing layer to remove the boron-containing layer formed on an upper surface of the stacked structure and a bottom surface of the recess portion, and to leave the boron-containing layer formed on a side surface of the stacked structure.

17. The method of claim 16, wherein
the boron-containing layer further contains nitrogen (N).

18. The method of claim 16, wherein
a metal containing layer containing a metal element contained in the stacked structure is formed on the bottom surface of the recess portion in the etching using the hard mask pattern as the mask, and
the metal-containing layer formed on the bottom surface of the recess portion is removed in the etching the boron-containing layer.

19. The method of claim 18, wherein
the metal-containing layer is formed on a side surface of the recess portion in addition to the bottom surface of the recess portion in the etching using the hard mask pattern as the mask, and
the metal-containing layer formed on the side surface of the recess portion remains in the etching the boron-containing layer.

20. The method of claim 18, wherein
the metal-containing layer contains at least one element selected from hafnium (Hf), tungsten (W), titanium (Ti), aluminum (Al), iron (Fe), cobalt (Co), platinum (Pt), and ruthenium (Ru).
